(19) United States
(12) Patent Application Publication
(10) Pub. No.: US 2025/0226248 A1
(43) Pub. Date: Jul. 10, 2025

(54) SUBSTRATE PROCESSING SYSTEM, SUBSTRATE PROCESSING APPARATUS, SUBSTRATE PROCESSING METHOD, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Norihito SHINOZAWA, Toyama-shi (JP); Kazuhide ASAI, Toyama-shi (JP); Osamu UEDA, Toyama-shi (JP); Tetsuyuki MAEDA, Toyama-shi (JP); Shuai YUAN, Toyama-shi (JP); Akihiko YONEDA, Toyama-shi (JP)

(73) Assignee: KOKUSAI ELECTRIC CORPORATION, Tokyo (JP)

(21) Appl. No.: 19/089,984

(22) Filed: Mar. 25, 2025

Related U.S. Application Data
(63) Continuation of application No. PCT/JP2023/034638, filed on Sep. 25, 2023.

(30) Foreign Application Priority Data
Dec. 26, 2022 (JP) 2022-208978

(51) Int. Cl. H01L 21/67; G05B 19/418; H01L 21/66

(52) U.S. Cl. CPC H01L 21/67253; G05B 19/41875; H01L 22/20; G05B 2219/34475

(57) ABSTRACT

There is provided a technique that includes: a process chamber configured to process a substrate; a memory configured to store sensor data obtained from at least two sensors, which have a master-slave relationship and are capable of obtaining a same type of data; a monitor configured to, if the sensor data satisfies a predetermined condition, determine that the sensor corresponding to the sensor data is abnormal; a switch configured to, if the sensor determined to be abnormal is a master sensor, switch a slave sensor which is a sensor other than the master sensor among the sensors to a new master sensor; a calculator configured to calculate a processing time for the substrate from the sensor data of the master sensor; and a controller configured to obtain the processing time calculated by the calculator before processing the substrate and control the processing of the substrate using the obtained processing time.

### CROSS-REFERENCE TO RELATED APPLICATION

This application is a Bypass Continuation application of PCT International Application No. PCT/JP2023/034638, filed on Sep. 25, 2023, and designating the United States, the international application being based upon and claiming the benefit of priority from Japanese Patent Application No. 2022-208978, filed on Dec. 26, 2022, the entire contents of which are incorporated herein by reference.

### TECHNICAL FIELD

The present disclosure relates to a substrate processing system, a substrate processing apparatus, a substrate processing method, a method of manufacturing a semiconductor device, and a recording medium.

### BACKGROUND

A substrate processing apparatus performs a film formation process using information (hereinafter referred to as a “recipe”) that indicates the procedure and conditions for forming a semiconductor film on a substrate. However, there may be cases where the expected film formation results cannot be obtained due to external factors such as fluctuations in air pressure.

In the related art, as a method for dealing with the fluctuations of external factors, there is a method of measuring the current air pressure before executing a recipe, calculating the optimal film formation time of the recipe according to the measured air pressure, and executing the recipe. However, if a sensor for measuring the state of the external factors breaks down, it may not be possible to calculate the film formation time before starting the recipe, making it difficult to obtain the expected film formation results.

### SUMMARY

Some embodiments of the present disclosure provide a technique capable of, even if a sensor breaks down, obtaining expected film formation results by correcting the film formation time before starting a recipe.

According to one embodiment of the present disclosure, there is provided a technique including a process chamber configured to process a substrate; a memory configured to store sensor data obtained from at least two sensors, which have a master-slave relationship and are capable of obtaining a same type of data; a monitor configured to, if the sensor data satisfies a predetermined condition, determine that the sensor corresponding to the sensor data satisfying the predetermined condition is abnormal; a switch configured to, if the sensor determined to be abnormal is a master sensor which is a main sensor among the at least two sensors, switch a slave sensor which is a sensor other than the master sensor among the at least two sensors to a new master sensor; a calculator configured to calculate a processing time for the substrate from the sensor data of the master sensor; and a controller configured to obtain the processing time calculated by the calculator before processing the substrate and to control the processing of the substrate using the obtained processing time.

### BRIEF DESCRIPTION OF DRAWINGS

The accompanying drawings, which are incorporated in and constitute a part of the specification, illustrate embodiments of the present disclosure.

FIG. 1 is a block diagram showing a substrate processing system according to embodiments.

FIG. 2 is a block diagram showing an overview of a management server in the block diagram of FIG. 1.

FIG. 3 is a block diagram showing an overview of a substrate processing apparatus in the block diagram of FIG. 1.

FIG. 4 is a perspective view schematically showing an example of the substrate processing apparatus.

FIG. 5 is a schematic configuration diagram of a process furnace in the substrate processing apparatus of FIG. 4.

FIG. 6 is a cross-sectional view of the process furnace of FIG. 5.

FIG. 7 is a flowchart showing an overview of sensor monitoring and substrate processing in the substrate processing system.

FIG. 8 is a flowchart showing sensor monitoring.

FIG. 9 is a flowchart showing individual abnormality determination for a sensor.

FIG. 10 is a flowchart showing first abnormality determination for the sensor.

FIG. 11 is a flowchart showing second abnormality determination for the sensor.

FIG. 12 is a flowchart showing abnormality determination between sensors.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

Hereinafter, embodiments of the present disclosure will be described with reference to the drawings. Drawings used in the following description are schematic, and the dimensional relationships of respective elements, the ratios of respective elements, and the like shown in the drawings do not necessarily match the actual ones. Furthermore, the dimensional relationships of respective elements, the ratios of respective elements, and the like do not necessarily match between multiple drawings. Moreover, a symbol that appears in common in respective drawings indicates a common configuration even if not mentioned in the description of respective drawings. In addition, each element mentioned in the following description is not limited to one, and may be present in multiple numbers, unless otherwise specified.

### (1) Substrate Processing System

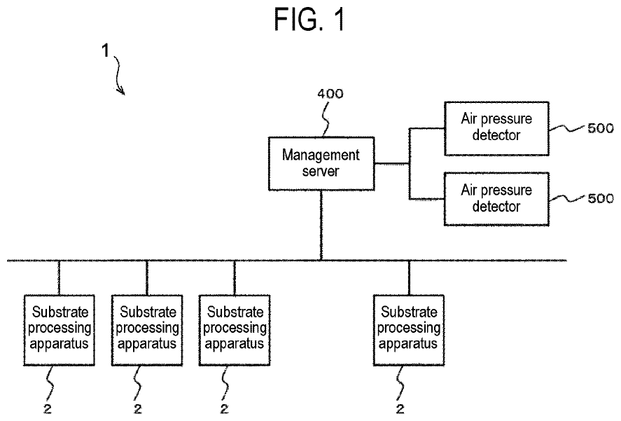

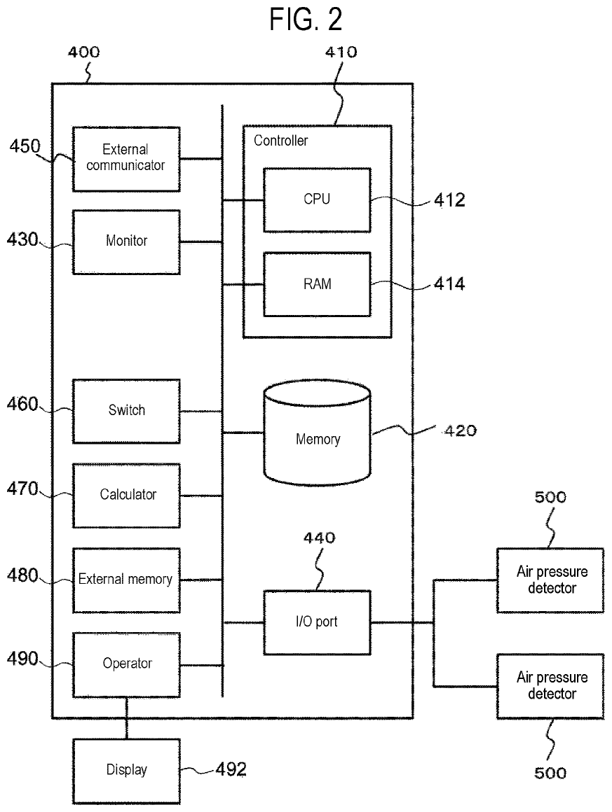

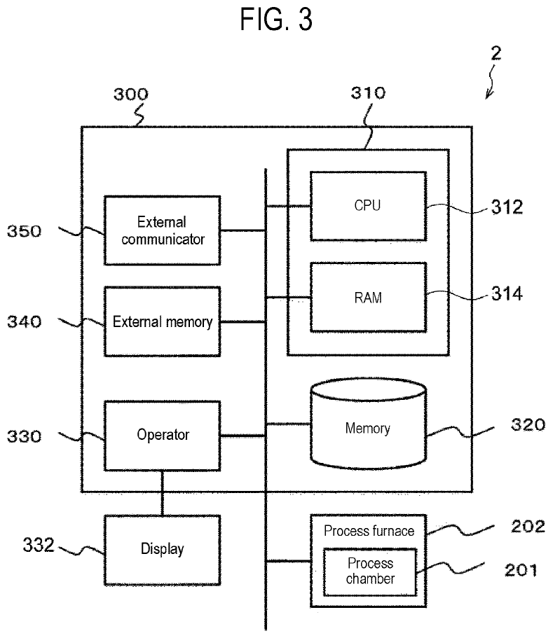

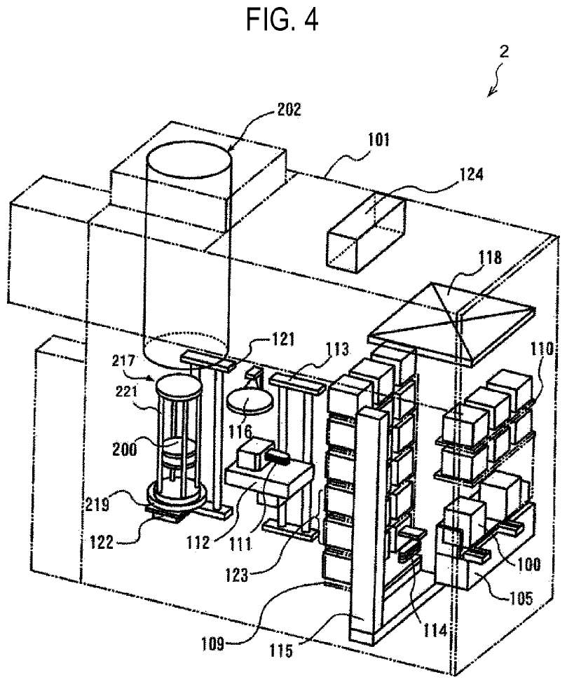

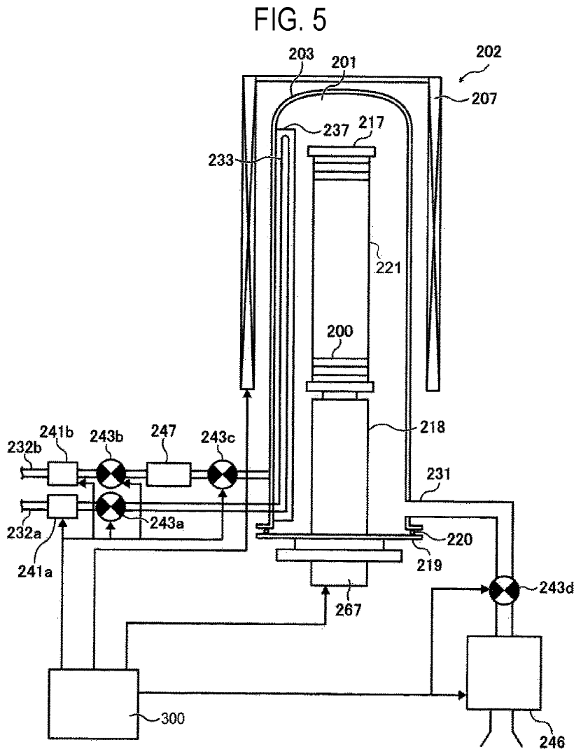

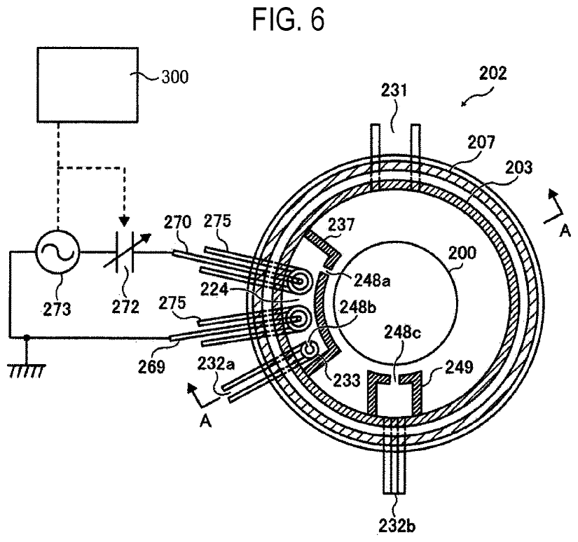

FIG. 1 is a block diagram showing a substrate processing system according to embodiments. FIG. 2 is a block diagram showing an overview of a management server in the block diagram of FIG. 1. FIG. 3 is a block diagram showing an overview of a substrate processing apparatus in the block diagram of FIG. 1. FIG. 4 is a perspective view schematically showing an example of the substrate processing apparatus. FIG. 5 is a schematic configuration diagram of a process furnace in the substrate processing apparatus of FIG. 4. FIG. 6 is a cross-sectional view of the process furnace of FIG. 5. Since the same reference numeral in each figure designates essentially the same element, the element will be described once and descriptions in other figures will be omitted.

As shown in FIG. 1, the substrate processing system 1 is composed of at least one substrate processing apparatus 2, a management server 400, and two or more air pressure detector 500, which are connected to each other via a network. One of the air pressure detector 500 functions as a master sensor, and the other functions as a slave sensor. That is, at least one substrate processing apparatus 2 is controlled by the management server 400 in a group management system.

As shown in FIG. 2, the management server 400 includes a controller 410, a memory 420, a monitor 430, an external communicator 450 that communicates with a main controller 300 (described later), an I/O port 440 to which an external device is connected, a switch 460, a calculator 470, an external memory 480, and an operator 490 that includes a display 492. An air pressure detector 500 is connected to the management server 400 via the I/O port 440. The controller 410 is composed of a CPU 412 and a RAM 414, and executes a control program for the management server 400 stored in the memory 420. The memory 420 stores a program for executing abnormality determination (described later) in addition to the control program for the management server 400. At the same time, the memory 420 stores atmospheric pressure data inputted from the pressure detector 500 serving as a master sensor and a slave sensor via the I/O port 440 as sensor data used to calculate a processing time as a processing condition for a substrate. The monitor 430 determines that the air pressure detector 500 corresponding to the sensor data stored in the memory 420 is abnormal if the sensor data stored in the memory 420 satisfies a predetermined condition. If the air pressure detector 500 determined to be abnormal is the master sensor, the switch 460 switches the air pressure detector 500, which is the slave sensor, to a new master sensor. The calculator 470 calculates the processing time for the substrate from the sensor data of the air pressure detector 500, which is the master sensor. The external communicator 450 transmits the processing time for the substrate adjusted by the calculator 470 to the main controller 300. The external memory 480 stores a part of the sensor data in place of the memory 420, thereby substantially expanding the capacity of the memory 420. The operator 490 is a part where an operator executes input related to the operation of the management server 400, and includes a display 492 that is capable of displaying the processing state of the substrate by the substrate processing apparatus 2 and the result of the abnormality determination by the monitor 430. In this specification, the processing time means the time during which the processing continues. These hold true in the following description.

As shown in FIG. 3, the substrate processing apparatus 2 includes a process furnace 202 having a process chamber 201 (see FIG. 5), and a main controller 300 for controlling the processing of substrates in the process furnace 202. The main controller 300 includes a controller 310, a memory 320, an operator 330 having a display 332, an external memory 340, and an external communicator 350. The external communicator 350 communicates with the management server 400 via the external communicator 450 described above. This communication includes the processing time for the substrate received from the external communicator 450 of the management server 400. The controller 310 is composed of a CPU 312 and a RAM 314, and executes a control program for controlling the processing of substrates in the process furnace 202, which is stored in the memory 320, based on various data such as recipe data and apparatus parameters as processing conditions for the substrates stored in the memory 320 and the external memory 340, and the processing time for the substrate received from the management server 400. The operator 330 is an interface used when the user operates the main controller 300, and the information related to an operation is displayed on the display 332.

The configuration of the substrate processing apparatus 2 according to the present embodiments will be described with reference to FIG. 4. As shown in FIG. 4, the substrate processing apparatus 2 of the present disclosure, which uses a cassette 100 storing a plurality of wafers 200 as substrates made of silicon or the like, includes a housing 101. A cassette stage (substrate container delivery table) 105 is installed inside the housing 101 at a cassette loading/unloading port (not shown). The cassette 100 is loaded onto the cassette stage 105 by an in-process transfer device (not shown), and is also unloaded from the cassette stage 105.

A cassette shelf (substrate container mounting shelf) 109 is installed approximately at the center of the housing 101 in the front-rear direction, and the cassette shelf 109 is configured to store a plurality of cassettes 100 in a plurality of rows and a plurality of stages. The cassette shelf 109 is provided with a delivery shelf 123 on which the cassettes 100 are stored. In addition, a spare cassette shelf 110 is provided above the cassette stage 105, and is configured to store the cassettes 100 in a spare manner. A cassette elevator (substrate container elevating mechanism) 115 capable of moving up and down while holding the cassette 100 and a cassette delivery machine 114 are arranged between the cassette stage 105 and the cassette shelf 109. The cassette elevator 115 and the cassette delivery machine 114 are configured to transfer the cassettes 100 between the cassette stage 105, the cassette shelf 109, and the spare cassette shelf 110 through a continuous operation.

A substrate delivery machine 112 capable of rotating or linearly moving the wafers 200 in the horizontal direction and a delivery elevator 113 for raising and lowering the substrate delivery machine 112 are arranged behind the cassette shelf 109. The delivery elevator 113 is installed at the right end of the housing 101. By the continuous operations of the delivery elevator 113 and the substrate delivery machine 112, the wafers 200 are charged to and discharged from the boat (substrate holding means) 217 using tweezers (substrate holders) 111 of the substrate delivery machine 112 as a mounting portion for the wafer 200.

The process furnace 202 is provided on the rear upper side of the housing 101. The lower end of the process furnace 202 is configured to be opened and closed by a furnace port shutter (furnace port opening/closing mechanism) 116. A boat elevator (substrate holder elevating mechanism) 121 is provided below the process furnace 202 as an elevator mechanism for elevating the boat 217 toward and away from the process furnace 202. A seal cap 219 as a lid is horizontally installed on an elevating member 122 as a connector connected to an elevating platform of the boat elevator 121. The seal cap 219 is configured to support the boat 217 vertically and to be able to close the lower end of the process furnace 202. The boat 217 as a substrate holding means includes a plurality of boat pillars 221 and is configured to horizontally hold a plurality of wafers 200 (e.g., about 50 to 150 wafers) in a vertically aligned state with their centers aligned with each other.

As shown in FIG. 4, on the upper side of the cassette shelf 109, a clean unit 118 composed of a supply fan and a dust filter is installed to supply a clean air, which is an atmosphere obtained by purifying the outside air flowing inward from a duct 124. This clean unit 118 is configured to circulate the clean air inside the housing 101.

Next, the operation of the substrate processing apparatus 2 of the present disclosure will be described. As shown in FIG. 4, the cassette 100 is loaded through a cassette loading/unloading port, and is mounted on the cassette stage 105. Next, the cassette 100 is automatically transferred and delivered to a designated shelf position of the cassette shelf 109 or the spare cassette shelf 110, and is temporarily stored thereon. After this primary storage, the cassette 100 is delivered from the cassette shelf 109 or the spare cassette shelf 110 to the delivery shelf 123, or directly transferred to the delivery shelf 123.

When the cassette 100 is delivered to the delivery shelf 123, the wafer 200 is picked up from the cassette 100 by the tweezers 111 of the substrate delivery machine 112 through a substrate entrance, and is charged onto the boat 217. After delivering the wafer 200 to the boat 217, the substrate delivery machine 112 returns to the cassette 100 and charges the next wafer 200 onto the boat 217.

When a pre-specified number of wafers 200 are charged onto the boat 217, the lower end of the process furnace 202, which has been closed by the furnace port shutter 116, is opened by the furnace port shutter 116. Next, the boat 217 holding the group of wafers 200 is loaded into the process furnace 202 as the seal cap 219 is raised by the boat elevator 121.

After loading the wafers 200, arbitrary processing is performed on the wafers 200 in the process furnace 202. After the processing, the wafers 200 and the cassette 100 are unloaded to the outside of the housing 101 through a reverse procedure with respect to the above-mentioned procedure.

Next, the above-mentioned process furnace 202 will be described in detail with reference to FIGS. 5 and 6. FIG. 5 is a schematic configuration diagram of the vertical substrate process furnace preferably used in the embodiments of the present disclosure, in which the process furnace 202 portion is shown in a vertical cross section. FIG. 6 is a schematic configuration diagram of the vertical substrate process furnace preferably used in the embodiments of the present disclosure, in which the process furnace 202 portion shown in horizontal a cross section.

The substrate processing apparatus 2 used in the present embodiments include a main controller 300 having a controller 310 (see FIG. 2). The main controller 300 controls the operations of the respective parts constituting the substrate processing apparatus 2 and the process furnace 202.

A reaction tube 203 as a reaction container for processing wafers 200 is provided inside a heater 207, which is a heating device (heating means). The lower end opening of the reaction tube 203 is airtightly closed by a seal cap 219, which is a lid, via an O-ring 220, which is an airtight member. At least the reaction tube 203 and the seal cap 219 form a process chamber 201. A boat 217, which is a substrate holding means, is installed upright on the seal cap 219 via a boat support stand 218. The boat support stand 218 is a holder for holding the boat 217. The boat 217 is inserted into the process chamber 201. A plurality of wafers 200 to be batch-processed are stacked on the boat pillars 221 of the boat 217 in a horizontal posture and in multiple stages in the tube axis direction. The heater 207 heats the wafers 200 inserted into the process chamber 201 to a predetermined temperature.

Two gas supply pipes 232a and 232b are installed as supply paths for supplying a plurality of types of gases (two types of gases in this case) to the process chamber 201. Here, a reaction gas is supplied from the first gas supply pipe 232a into the process chamber 201 through a first mass flow controller (MFC) 241a which is a flow rate control device (flow rate control means), a first valve 243a which is an on-off valve, and a buffer chamber 237 formed in the reaction tube 203 described later. A reaction gas is supplied from the first gas supply pipe 232b into the process chamber 201 through a second MFC 241b which is a flow rate control device (flow rate control means), a second valve 243b which is an on-off valve, a gas reservoir 247, a third valve 243c which is an on-off valve, and a gas supply part 249 described later.

The process chamber 201 is connected to a vacuum pump 246, which is an exhaust device (exhaust means), via a gas exhaust pipe 231 for exhausting a gas through a fourth valve 243d, so that the process chamber 201 may be evacuated to a vacuum. The fourth valve 243d is an on-off valve that may be opened and closed to start and stop the evacuation of the process chamber 201. The valve opening degree of the fourth valve 243d may be adjusted to regulate the pressure.

In the arc-shaped space between the wafers 200 and the inner wall of the reaction tube 203 constituting the process chamber 201, a buffer chamber 237 serving as a gas dispersion space is provided along the stacking direction of the wafers 200 on the inner wall from the lower portion to the upper portion of the reaction tube 203. First gas supply holes 248a serving as supply holes for supplying a gas are formed at the end of the wall of the buffer chamber 237 adjacent to the wafers 200. The first gas supply holes 248a are opened toward the center of the reaction tube 203. The first gas supply holes 248a have the same opening area from the lower portion to the upper portion, and are provided at the same opening pitch.

At the end of the buffer chamber 237 opposite to the end where the first gas supply holes 248a are formed, a nozzle 233 is also arranged to extend from the lower portion to the upper portion of the reaction tube 203 along the stacking direction of the wafers 200. The nozzle 233 is provided with second gas supply holes 248b which are supply holes for supplying a plurality of gases. When the pressure difference between the buffer chamber 237 and the process chamber 201 is small, the opening area of the second gas supply holes 248b may have the same opening area and the same pitch from the upstream side to the downstream side of the gas flow. On the other hand, when the pressure difference is large, the opening area may be increased, or the opening pitch may be decreased from the upstream side to the downstream side.

In the present embodiments, the opening area of the second gas supply holes 248b is gradually increased from the upstream side to the downstream side. With this configuration, the gas is injected from the respective second gas supply holes 248b into the buffer chamber 237 at approximately the same flow rate but at different gas flow velocities. Then, after the particle speed difference of the gas injected from the respective second gas supply holes 248b in the buffer chamber 237 is alleviated, the gas is injected into the process chamber 201 from the first gas supply holes 248a. Therefore, the gas injected from the respective second gas supply holes 248b may have a uniform flow rate and a uniform flow velocity when injected from the respective first gas supply holes 248a.

Furthermore, in the buffer chamber 237, a first rod-shaped electrode 269, which is a first electrode having an elongated structure, and a second rod-shaped electrode 270, which is a second electrode, are arranged while being protected from the upper portion to the lower portion by an electrode protection tube 275, which is a protective tube that protects the electrodes. One of the first rod-shaped electrode 269 and the second rod-shaped electrode 270 is connected to a high-frequency power source 273 via a matcher 272, and the other is connected to the earth, which is a reference potential. As a result, plasma is generated in a plasma generation region 224 between the first rod-shaped electrode 269 and the second rod-shaped electrode 270.

The electrode protection tube 275 has a structure that allows each of the first rod-shaped electrode 269 and the second rod-shaped electrode 270 to be inserted into the buffer chamber 237 while being isolated from the atmosphere of the buffer chamber 237. If the atmosphere inside the electrode protection tube 275 is the same as the outside air (atmosphere), each of the first rod-shaped electrode 269 and the second rod-shaped electrode 270 inserted into the electrode protection tube 275 is oxidized by the heating of the heater 207. Therefore, there is provided an inert gas purge mechanism for filling or purging the inside of the electrode protection tube 275 with an inert gas such as nitrogen to keep the oxygen concentration sufficiently low and prevent the oxidation of the first rod-shaped electrode 269 or the second rod-shaped electrode 270.

Furthermore, a gas supply part 249 is provided on the inner wall of the reaction tube 203 at a position rotated about 120° along the inner circumference from the position of the first gas supply holes 248a. This gas supply part 249 is a supply part that shares the gas supply species with the buffer chamber 237 when multiple types of gases are alternately supplied to the wafers 200 one type at a time in film formation by an ALD method.

Just like the buffer chamber 237, this gas supply part 249 also has third gas supply holes 248c configured to supply gases and arranged at the same pitch at positions adjacent to the wafers 200. The gas supply part 249 is connected to the second gas supply pipe 232b at the lower portion thereof.

When the pressure difference between the gas supply part 249 and the process chamber 201 is small, the third gas supply holes 248c may be the same opening area and the same opening pitch from the upstream side to the downstream side of the gas flow. On the other hand, when the pressure difference is large, the opening area may be increased or the opening pitch may be decreased from the upstream side to the downstream side. In the present embodiments, the opening area of the third gas supply holes 248c is gradually increased from the upstream side to the downstream side.

A boat 217 having boat pillars 221 on which a plurality of wafers 200 are placed at equal intervals in multiple stages is installed at the center of the reaction tube 203. The boat 217 may be moved into and out of the reaction tube 203 by a boat elevator mechanism (not shown). Furthermore, a boat rotation mechanism 267, which is a rotation device (rotation means) for rotating the boat 217 to improve the uniformity of processing, is provided. By rotating the boat rotation mechanism 267, the boat 217 held by the boat support stand 218 is rotated.

A main controller 300 as a control means is connected to the first and second MFCs 241a and 241b, the first to fourth valves 243a, 243b, 243c and 243d, the heater 207, the vacuum pump 246, the boat rotation mechanism 267, the boat elevating mechanism (not shown), the high-frequency power source 273, and the matcher 272. With this configuration, the main controller 300 executes the flow rate adjustment of the first and second MFCs 241a and 241b, the opening/closing operations of the first to third valves 243a, 243b and 243c, the opening/closing and pressure regulation operations of the fourth valve 243d, the temperature adjustment of the heater 207, the start and stop of the vacuum pump 246, the rotation speed adjustment of the boat rotation mechanism 267, the control of the elevating operation of the boat elevating mechanism, the control of the power supply of the high-frequency power source 273, and the impedance control by the matcher 272.

As described above, the substrate processing system 1 according to the present embodiments include: a process chamber 201 configured to process a wafer 200; a memory 420 configured to store sensor data obtained from at least two sensors (air pressure detector 500) having a master-slave relationship capable of obtaining the same type of data; a monitor 430 configured to, if the stored sensor data satisfies a predetermined condition, determine that the sensor corresponding to the stored sensor data is abnormal; a switch 460 configured to, if the sensor determined to be abnormal is a master sensor which is a main sensor among the two sensors, switch a slave sensor which is a sensor other than the master sensor among the two sensors to a new master sensor; a calculator 470 configured to calculate a processing time for the substrate from the sensor data of the master sensor; and a controller 410 configured to obtain the processing time calculated by the calculator 470 before processing the substrate and control the processing of the substrate using the obtained processing time.

With this configuration, even if the master sensor which is one of the two sensors breaks down, the sensor data from the slave sensor which is the other sensor is continuously acquired, which makes it possible to adjust the processing time of the substrate using the acquired sensor data. This makes it possible to adjust the film formation conditions in response to changes in the environment that affect the film formation, and to process the substrate with a consistent quality.

The sensor data acquired from the sensor includes the atmospheric pressure outside the process furnace 202. However, the sensor data is not limited thereto. In addition, for example, the air temperature outside the process furnace 202, the flow rate of the gas flowing into the process furnace 202, or the pressure inside the process furnace 202 may be acquired as the sensor data.

In the substrate processing system 1, it is preferable that if the sensor data does not satisfy the predetermined condition, the monitor 430 determines that the state of the sensor corresponding to the sensor data is normal. In this case, the switch 460 does nothing as a result, thereby reducing the processing load on the controller 410.

Furthermore, in the above-described substrate processing system 1, it is preferable that if the sensor determined to be abnormal is the slave sensor, the switch 460 maintains the master-slave relationship of the sensors. In this case, the master sensor that is currently acquiring sensor data is determined to be normal. Therefore, there is no effect on the adjustment of the processing time. In this case, too, the switch 460 does nothing as a result, thereby reducing the processing load on the controller 410.

According to the above-described substrate processing system 1, it is possible to execute a method of manufacturing a semiconductor device, including: storing sensor data, which is data acquired from at least two sensors having a master-slave relationship capable of acquiring the same type of data; if the stored sensor data satisfies a predetermined condition, determining that the sensor corresponding to the stored sensor data is abnormal; if the sensor determined to be abnormal is a master sensor, which is a main sensor among the sensors, switching a slave sensor, which is a sensor other than the master sensor among the sensors, to a new master sensor; calculating a processing time for a substrate from the sensor data of the master sensor; and processing the substrate using the processing time.

The memory 420 or the external memory 480 of the management server 400, the memory 320 or the external memory 340 of the main controller 300, or a computer-readable recording medium records therein a control program that causes a computer to have the substrate processing apparatus 2 execute each step in the method of manufacturing a semiconductor device. That is, the control program causes a computer to have the substrate processing apparatus 2 execute: storing sensor data, which is data acquired from at least two sensors having a master-slave relationship capable of acquiring the same type of data; if the stored sensor data satisfies a predetermined condition, determining that the sensor corresponding to the stored sensor data is abnormal; if the sensor determined to be abnormal is a master sensor, which is a main sensor among the sensors, switching a slave sensor, which is a sensor other than the master sensor among the sensors, to a new master sensor; calculating a processing time for a substrate from the sensor data of the master sensor; and processing the substrate using the processing time. The control program may be recorded in a computer-readable recording medium. Alternatively, a computer-readable recording medium that records the control program may be used.

Moreover, the above-described substrate processing system 1 preferably includes an operator 490 having a display 492 capable of displaying the processing state of the wafer 200. The controller 410 preferably receives a notification from the monitor 430 and notifies the operator 490 of an abnormality. Furthermore, it is preferable that the operator 490 receives a notification from the controller 410 and instructs the display 492 to display the notification result. With this configuration, it is possible to notify an operator operating the substrate processing system 1 that a sensor is abnormal.

Furthermore, in the above-described substrate processing system 1, if the mater sensor is abnormal, it is preferable that the display 492 displays a message indicating that an abnormality that requires switching between the master sensor and the slave sensor has occurred. Moreover, if the slave sensor is abnormal, it is preferable that the display 492 displays a message indicating that an abnormality that does not require switching between the master sensor and the slave sensor has occurred. In other words, by setting different alarm levels for when an abnormality has occurred in the master sensor and when an abnormality has occurred in the slave sensor, it is possible to allow an operator to intuitively grasp the abnormality situation.

In the substrate processing apparatus 2 shown in FIG. 3, as a modification, the memory 320 may have the function of the memory 420 among the functions of the management server 400, and may further have the functions of the monitor 430, the switch 460, and the calculator 470. In addition, an air pressure detector 500 serving as a sensor may be connected to the substrate processing apparatus 2 via an I/O port (not shown).

That is, the substrate processing apparatus 2 may include: a process chamber 201 configured to process a wafer 200; a memory 320 configured to store sensor data obtained from at least two sensors having a master-slave relationship capable of obtaining the same type of data; a monitor 430 configured to, if the stored sensor data satisfies a predetermined condition, determine that the sensor corresponding to the stored sensor data is abnormal; a switch 460 configured to, if the sensor determined to be abnormal is a master sensor, which is a main sensor among the sensors, switch a slave sensor, which is a sensor other than the master sensor among the sensors, to a new master sensor; a calculator 470 configured to calculate a processing time for the wafer 200 from the sensor data of the master sensor; and a controller 310 configured to obtain the processing time calculated by the calculator 470 before processing the wafer 200 and control the processing of the wafer 200 using the obtained processing time.

With this configuration, even if a group management system as shown in FIG. 1 is not constructed, even when one of the sensors, i.e., a master sensor, breaks down, a single substrate processing apparatus 2 may continuously acquire sensor data from the other sensor, i.e., a slave sensor. Then, the acquired sensor data may be used to adjust the processing time of the substrate. This makes it possible to adjust the film formation conditions in response to changes in the environment that affects film formation, and to process the substrate with a consistent quality.

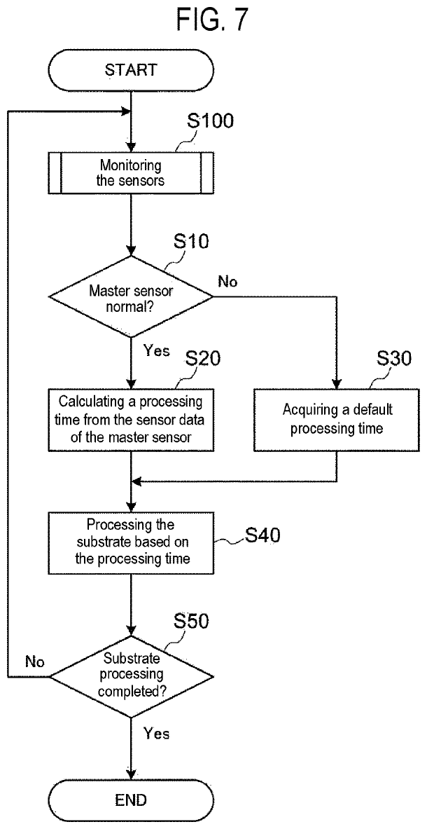

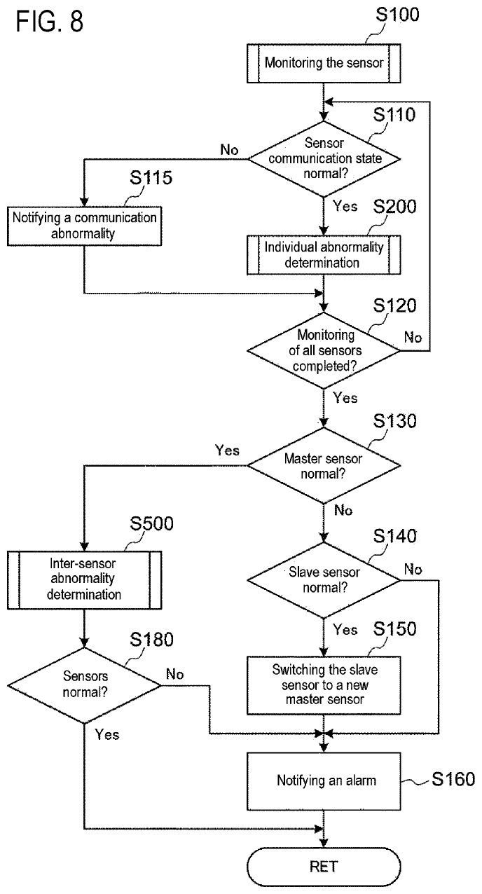

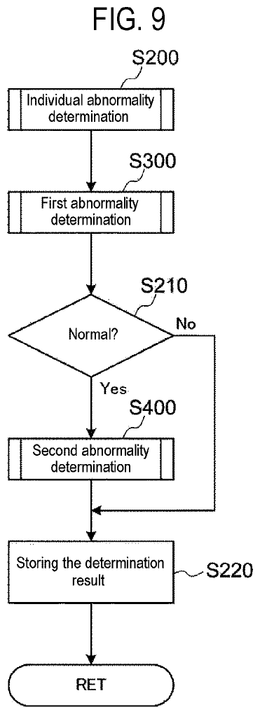

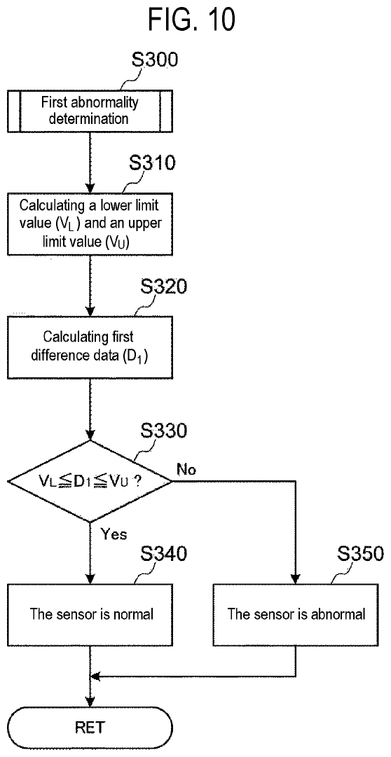

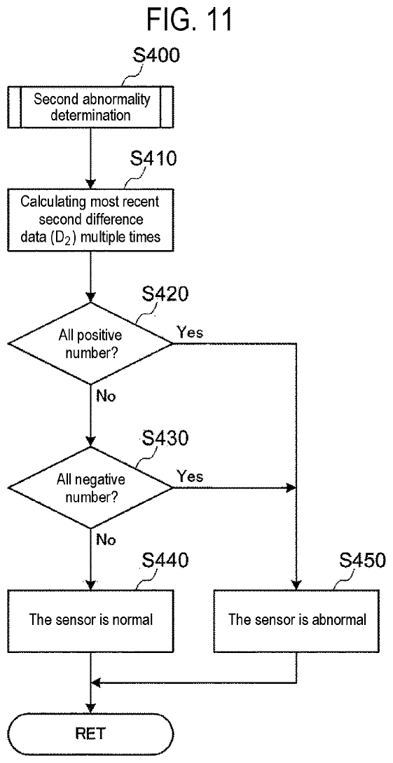

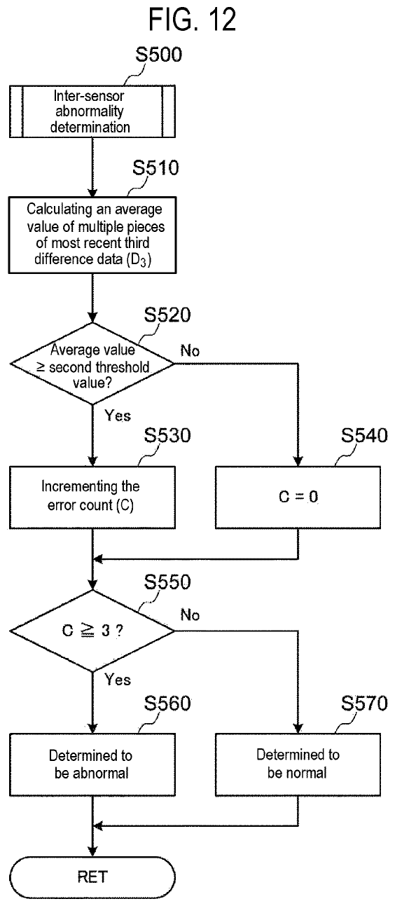

Hereinafter, the monitoring of the sensor (air pressure detector 500) and the substrate processing based on the monitoring in the substrate processing system 1 according to the present embodiments will be described with reference to FIGS. 7 to 12. FIG. 7 is a flowchart showing an overview of substrate processing in the substrate processing system 1. FIG. 8 is a flowchart showing sensor monitoring. FIG. 9 is a flowchart showing individual abnormality determination for the sensor. FIG. 10 is a flowchart showing first abnormality determination for the sensor. FIG. 11 is a flowchart showing second abnormality determination for the sensor. FIG. 12 is a flowchart showing abnormality determination between the sensors.

When the substrate processing starts in the substrate processing system 1, first, in step S100 in FIG. 7, a sensor monitoring process shown in FIG. 8 is executed.

In the sensor monitoring process (S100) shown in FIG. 8, first, in step S110, the monitor 430 determines whether the communication state of the first sensor (one of the multiple sensors) with the management server 400 is normal. If the communication state of the first sensor is determined to be normal, the process proceeds to step S200, and the individual abnormality determination process shown in FIG. 9 is executed.

On the other hand, if the communication state of the first sensor is determined not to be normal, the process proceeds to step S115 where the monitor 430 notifies the controller 410 that a communication abnormality has occurred. The controller 410, upon receiving this notification, may notify the operator 490 of the occurrence of the communication abnormality, and may cause the display 492 to issue a predetermined alarm notification. That is, in the substrate processing system 1 according to the present embodiments, the monitor 430 monitors the mutual communication state between the master sensor and the slave sensor, and notifies the controller 410 of an abnormality in the communication state when the abnormality is detected. This makes it possible to notify an operator that an abnormality has occurred in the communication state. After step S115, the process proceeds to step S120, which will be described later.

In the individual abnormality determination process (S200) shown in FIG. 9, the process first proceeds to step S300 where the first abnormality determination process shown in FIG. 10 is executed.

In the first abnormality determination process shown in FIG. 10, first, in step S310, for the air pressure value detected by the sensor related to the abnormality determination, the monitor 430 calculates a first threshold value related to the normal range of the first difference data (D₁), which is a difference between the most recent sensor data (specifically, the air pressure value) and the immediately previous sensor data. Here, the first threshold value is specifically represented by a lower limit (V_{L}) and an upper limit (V_{U}) of the air pressure difference.

The lower limit (V_{L}) and the upper limit (V_{U}) are calculated, for example, as follows. First, a difference between each of multiple (e.g., 20) pieces of most recent sensor data and the immediately previous sensor data stored in the memory 420 is calculated. Then, for multiple differences, an average value (μ₁) and a standard deviation (σ) are calculated, and the lower limit (V_{L}) and the upper limit (V_{U}) are found based on these values using the following equations.

$${V}_{L} = {μ}_{1} - 3 σ$$

$${V}_{U} = {μ}_{1} + 3 σ$$

The coefficient by which σ is multiplied in each of the above equations is not limited to 3, but may be increased or decreased as appropriate depending on the required monitoring accuracy.

Next, in step S320, the monitor 430 calculates first differential data (D₁) between the most recent sensor data stored in the memory 420 and the immediately previous sensor data. Then, in step S330, it is determined whether the first differential data (D₁) falls within a range equal to or greater than the lower limit value (V_{L}) and equal to or smaller than the upper limit value (V_{U}). If it is determined that the first differential data (D₁) falls within this range, then in step S340, information indicating that the sensor is normal is stored in the memory 420 (or the external memory 480). On the other hand, if it is determined that the first differential data (D₁) does not fall within this range, then in step S350, information indicating that the sensor is abnormal is stored in the memory 420 (or the external memory 480).

That is, in the substrate processing system 1 according to the present embodiments, the monitor 430 compares the first difference data, which is a difference between specific sensor data and immediately previous sensor data stored in the memory 420, with a first threshold value defined in advance to determine an abnormality of the sensor. Furthermore, the first threshold value is calculated based on the average value and standard deviation of multiple consecutive pieces of first difference data. Since the first threshold value is calculated sequentially based on multiple pieces of past sensor data in this way, it is possible to perform more accurate and timely abnormality determination.

As described above, in both the case where it is determined that the sensor is normal (S340) and the case where it is determined that the sensor is abnormal (S350), the process returns (RET) to the individual abnormality determination process shown in FIG. 9. That is, the process proceeds to step S210 where the monitor 430 determines whether the sensor is normal. If the sensor is abnormal, the process proceeds to step S220 where the determination result is stored in the memory 420 (or the external memory 480). Then, the process returns (RET) to the sensor monitoring process shown in FIG. 8. On the other hand, if the sensor is normal, the process proceeds to step S400 where the second abnormality determination process shown in FIG. 11 is executed.

In the second abnormality determination process shown in FIG. 11, first, in step S410, the monitor 430 calculates second difference data (D₂) which is a difference between each of multiple (e.g., five) pieces of most recent sensor data and the immediately previous sensor data stored in the memory 420 as the numerical values of air pressure detected by the sensor related to the abnormality determination. Then, the process proceeds to step S420 where the monitor 430 determines whether the multiple pieces of second difference data (D₂) are all positive numbers, and if not, the process proceeds to step S430 where the monitor 430 determines whether the multiple pieces of second difference data (D₂) are all negative numbers.

If the multiple pieces of second difference data (D₂) are all positive numbers, the multiple pieces of most recent sensor data are determined to be on an increasing trend, and the information indicating that the sensor is abnormal is stored in the memory 420 (or the external memory 480) in step S450. If the multiple pieces of second difference data (D₂) are all negative numbers, the multiple pieces of most recent sensor data are determined to be on a decreasing trend, and the information indicating that the sensor is abnormal is stored in the memory 420 (or the external memory 480) in step S450.

On the other hand, if all of the multiple pieces of second difference data (D₂) are neither positive nor negative (in other words, if at least one of the multiple pieces of second difference data (D₂) is a positive number and at least one is a negative number, or if at least one is zero), the multiple pieces of most recent sensor data are determined to be neither on an increasing nor on a decreasing trend, and the information indicating that the sensor is normal is stored in the memory 420 (or the external memory 480) in step S440.

That is, in the substrate processing system 1 according to the present embodiments, the monitor 430 calculates second difference data, which is a difference between specific sensor data and immediately previous sensor data stored in the memory 420, a predetermined number of times in succession, and determines whether the sensor is abnormal based on the increasing/decreasing trend of the second difference data. Furthermore, the monitor 430 determines whether the sensor is abnormal if the second difference data shows a continuous increasing or decreasing trend. That is, for the information such as an atmospheric pressure, which is constantly fluctuating and does not easily show a simple increase or decrease, it is possible to determine whether the sensor is abnormal by observing the increasing/decreasing trend of the sensor data.

As described above, in both the case where it is determined that the sensor is normal (S440) and the case where it is determined that the sensor is abnormal (S450), the process returns (RET) to the individual abnormality determination process shown in FIG. 9. That is, the process proceeds to step S220. The determination result is stored in the memory 420 (or the external memory 480). Then, the process returns (RET) to the sensor monitoring process shown in FIG. 8.

In the sensor monitoring process shown in FIG. 8, it is determined in step S120 whether or not the monitoring of all sensors has been completed. If there is a sensor that has not yet been monitored, the process returns to step S110. If the communication status of that sensor is normal, the individual abnormality determination process in S200 is executed again for that sensor.

On the other hand, if it is determined in step S120 that the monitoring of all sensors has been completed, then in step S130, the monitor 430 refers to the memory 420 (or the external memory 480) to determine whether the master sensor is normal. If the master sensor is normal, the process proceeds to step S500, which will be described later. On the other hand, if the master sensor is abnormal, the process proceeds to step S140 where it is determined whether the slave sensor is normal. If the slave sensor is also abnormal, the process proceeds to step S160, which will be described later.

On the other hand, if the slave sensor is normal, the process proceeds to step S150 where the switch 460 switches the slave sensor to a new master sensor. That is, the sensor data that has been stored in the memory (or the external memory 480) as the sensor data of the slave sensor thus far is treated as the sensor data of the master sensor from step S150 onward. Then, the process proceeds to step S160, which will be described later.

If it is determined in step S130 that the master sensor is normal, the process proceeds to step S500 where the inter-sensor abnormality determination process shown in FIG. 12 is executed.

In the inter-sensor abnormality determination process (S500) shown in FIG. 12, first, in step S510, for the multiple (e.g., five) pieces of most recent sensor data stored in the memory 420 as numerical values of air pressure detected by the master sensor and the slave sensor, the monitor 430 calculates third difference data (D₃) which is a difference between the sensor data of the master sensor and the sensor data of the slave sensor. Next, the average value (μ₂) of the multiple pieces of third difference data (D₃) is calculated.

Then, the process proceeds to step S520 where the monitor 430 determines whether or not the average value (μ₂) is equal to or greater than a second threshold value, which is a predetermined threshold value. Here, when the sensor data is an atmospheric pressure, the second threshold value may be set to a predetermined pressure value (e.g., 1 hPa). If the average value (μ₂) is equal to or greater than the second threshold value, the process proceeds to step S530 where the error count (C) is incremented by 1. As referred to herein, the error count (C) is a parameter that counts the number of errors which are regarded as occurring when the determination in S520 is positive. When the process shown in FIG. 7 starts, the initial value of the error count (C) is zero. Then, the error count is incremented by 1 each time the process reaches step S530. On the other hand, if the average value (μ₂) is not equal to or greater than the second threshold value, the process proceeds to step S540 where the error count (C) is cleared and returns to the initial value of zero. In either case, the process proceeds to step S550.

In step S550, the monitor 430 determines whether the error count (C) is equal to or greater than 3 which is a determination threshold value. As referred to herein, the determination threshold value has the significance as a criterion indicating how many consecutive errors are required to be abnormal. The determination threshold value is not particularly limited to 3, and may be increased or decreased as appropriate according to the required accuracy of monitoring. If it is determined that the error count (C) is 3 or more, information indicating that the sensor is abnormal is stored in the memory 420 (or the external memory 480) in step S560. On the other hand, if it is determined that the error count is less than 3, information indicating that the sensor is normal is stored in the memory 420 (or the external memory 480) in step S570. In either case, the process returns (RET) to the sensor monitoring process shown in FIG. 8.

That is, in the substrate processing system 1 according to the embodiments, the monitor 430 calculates third difference data, which is a difference between the sensor data of the master sensor and the sensor data of the slave sensor stored in the memory 420, a predetermined number of times in succession, and then compares an average value calculated from the multiple pieces of third difference data with the second threshold value defined in advance to determine whether or not the sensor is abnormal. With this configuration, it is possible to know that any of the sensors is abnormal.

In the sensor monitoring process shown in FIG. 8, in step S180, the monitor 430 determines whether the error count difference between the sensors is normal. If the error count difference is determined to be normal, the process proceeds to step S10 of FIG. 7. On the other hand, if the error count difference is determined to be abnormal, the process proceeds to step S160.

In step S160, when both the master sensor and the slave sensor are determined to be abnormal (S130 and S140), when the slave sensor is determined to be normal but the master sensor is determined to be abnormal (S130, S140 and S150), or when either the master sensor or the slave sensor is determined to be abnormal (S180), the monitor 430 notifies the controller 410 of the fact. The controller 410 that has received the notification of the fact notifies the operator 490 of an abnormality. The operator that has received the notification of an abnormality causes the display 492 to notify the operator of the notification result by an alarm. In this notification, when the master sensor is abnormal, a relatively high level alarm is displayed on the display 492 to indicate that an abnormality that requires switching between the master sensor and the slave sensor has occurred. In addition, when only the slave sensor is abnormal, a relatively low level alarm is displayed on the display 492 to indicate that an abnormality that does not require switching between the master sensor and the slave sensor has occurred. When the process of step S160 is completed, the process proceeds to step S10 of FIG. 7.

In step S10 of FIG. 7, the controller 410 determines whether the master sensor is normal. The master sensor in this step includes both the master sensor which has been determined to be normal in step S130 of FIG. 8 and the master sensor which has been switched from the original slave sensor in step S150. If the master sensor is determined to be normal, the process proceeds to step S20 where the calculator 470 calculates a substrate processing time from the most recent sensor data of the master sensor stored in the memory 420. Then, the process proceeds to step S40.

Meanwhile, the determination in step S10 that the master sensor is abnormal means the determination in steps S130 and S140 of FIG. 8 that both the master sensor and the slave sensor are abnormal. In this case, the process proceeds to step S30 where the controller 410 acquires the default substrate processing time stored in the memory 420 without having to use the sensor data of either sensor. Then, the process proceeds to step S40.

That is, in the substrate processing system 1 according to the present embodiments, the controller 410 is capable of controlling the processing of the substrate using a predefined processing time when both the master sensor and the slave sensor are abnormal. This makes it possible to process the substrate even when the master sensor and the slave sensor are unavailable.

In step S40, the processing time calculated in step S20 or the processing time acquired in step S30 is transmitted to the external communicator 350 of the substrate processing apparatus 2 through the external communicator 450. In the substrate processing apparatus 2, the controller 310 adjusts the recipe data acquired from the memory 320 with the received processing time, and executes processing of the wafer 200 in the process furnace 202. Then, in step S50, the sensor monitoring process S100 and subsequent processes are repeated until it is determined that the processing of the wafer 200 has been completed.

In the above-described embodiments, there has been described the example in which the substrates are processed using the batch-type substrate processing apparatus that processes multiple substrates at a time. The present disclosure is not limited to the above-described embodiments, and may be suitably applied to, for example, a case where a single-substrate-type substrate processing apparatus that processes one or several substrates at a time is used. Furthermore, in the above-described embodiments, there has been described the example in which substrates are processed using the substrate processing apparatus having the hot-wall-type process furnace. The present disclosure is not limited to the above-described embodiments, and may be suitably applied to a case where substrates are processed using a substrate processing apparatus having a cold-wall-type furnace.

When using these substrate processing apparatuses, each process may be performed using the same process procedures and conditions as in the above-described embodiment sand modifications, and the same effects as in the above-described embodiments and modifications may be obtained.

The above-described embodiments and modifications may be used in appropriate combinations. The processing procedures and processing conditions in such a case may be the same as those of the above-described embodiments and modifications.

The disclosure of Japanese Patent Application No. 2022-208978, filed on Dec. 26, 2022, is incorporated herein by reference in its entirety. All documents, patent applications, and technical standards described herein are incorporated herein by reference to the same extent as if each individual document, patent application, and technical standard was specifically and individually indicated to be incorporated by reference.

According to the present disclosure in some embodiments, it is possible to provide a technique capable of, even if a sensor breaks down, obtaining expected film formation results by correcting the film formation time before starting a recipe.

While certain embodiments are described, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing system, comprising:
a process chamber configured to process a substrate;
a memory configured to store sensor data obtained from at least two sensors, which have a master-slave relationship and are capable of obtaining a same type of data;
a monitor configured to, if the sensor data satisfies a predetermined condition, determine that the sensor corresponding to the sensor data satisfying the predetermined condition is abnormal;
a switch configured to, if the sensor determined to be abnormal is a master sensor which is a main sensor among the at least two sensors, switch a slave sensor which is a sensor other than the master sensor among the at least two sensors to a new master sensor;
a calculator configured to calculate a processing time for the substrate from the sensor data of the master sensor; and
a controller configured to obtain the processing time calculated by the calculator before processing the substrate and to control the processing of the substrate using the obtained processing time.

2. The substrate processing system of claim 1, wherein if the sensor data does not satisfy the predetermined condition, the monitor determines that the state of the sensor corresponding to the sensor data not satisfying the predetermined condition is normal.

3. The substrate processing system of claim 1, wherein if the sensor determined to be abnormal is the slave sensor, the switch maintains the master-slave relationship of the sensors.

4. The substrate processing system of claim 1, wherein the monitor determines an abnormality of each of the at least two sensors by comparing first difference data, which is a difference between sensor data and immediately preceding sensor data stored in the memory, with a predetermined first threshold value.

5. The substrate processing system of claim 4, wherein the first threshold value is calculated based on an average value and a standard deviation of a plurality of consecutive pieces of first difference data.

6. The substrate processing system of claim 1, wherein the monitor obtains second difference data, which is a difference between sensor data and immediately preceding sensor data stored in the memory, a predetermined consecutive plurality of number of times, and determines an abnormality of each of the at least two sensors based on an increasing or decreasing trend of the second difference data.

7. The substrate processing system of claim 6, wherein if the second difference data continuously shows a continuous increasing trend or a continuous decreasing trend, the monitor determines that each of the at least two sensors is abnormal.

8. The substrate processing system of claim 1, wherein the monitor calculates third difference data, which is a difference between the sensor data of the master sensor and the sensor data of the slave sensor stored in the memory, a predetermined consecutive number of times, and then determines an abnormality of each of the at least two sensors by comparing an average value calculated from the third difference data with a predetermined second threshold value.

9. The substrate processing system of claim 1, further comprising:
an operator having a display capable of displaying the processing state of the substrate,
wherein the controller receives a notification from the monitor and notifies the operator of an abnormality.

10. The substrate processing system of claim 9, wherein the operator receives a notification from the controller and instructs the display to display a notification result.

11. The substrate processing system of claim 10, wherein if the master sensor is abnormal, the display displays a message indicating that an abnormality that requires switching the master-slave relationship of the sensors has occurred.

12. The substrate processing system of claim 11, wherein if the slave sensor is abnormal, the display displays a message indicating that an abnormality that does not require switching the master-slave relationship of the sensors has occurred.

13. The substrate processing system of claim 1, wherein the monitor monitors a mutual communication state between the master sensor and the slave sensor, and notifies the controller when an abnormality is detected in the mutual communication state.

14. The substrate processing system of claim 1, wherein the controller is capable of controlling the processing of the substrate using a predetermined processing time when both the master sensor and the slave sensor are abnormal.

15. A substrate processing apparatus, comprising:
a process chamber configured to process a substrate;
a memory configured to store sensor data obtained from at least two sensors, which have a master-slave relationship and are capable of obtaining a same type of data;
a monitor configured to, if the sensor data satisfies a predetermined condition, determine that the sensor corresponding to the sensor data satisfying the predetermined condition is abnormal;
a switch configured to, if the sensor determined to be abnormal is a master sensor which is a main sensor among the at least two sensors, switch a slave sensor which is a sensor other than the master sensor among the at least two sensors to a new master sensor;
a calculator configured to calculate a processing time for the substrate from the sensor data of the master sensor; and
a controller configured to obtain the processing time calculated by the calculator before processing the substrate and control the processing of the substrate using the obtained processing time.

16. A substrate processing method, comprising:
storing sensor data, which is data acquired from at least two sensors having a master-slave relationship and are capable of acquiring a same type of data;
if the sensor data satisfies a predetermined condition, determining that the sensor corresponding to the sensor data satisfying the predetermined condition is abnormal;
if the sensor determined to be abnormal is a master sensor, which is a main sensor among the at least two sensors, switching a slave sensor, which is a sensor other than the master sensor among the at least two sensors, to a new master sensor;
calculating a processing time for a substrate from the sensor data of the master sensor; and
processing the substrate using the processing time.

17. A method of manufacturing a semiconductor device, comprising the substrate processing method according to claim 16.

18. A non-transitory computer-readable recording medium storing a program that causes, by a computer, a substrate processing apparatus to perform a process, comprising the substrate processing method according to claim 16.
